(19) United States
(12) Patent Application Publication
(10) Pub. No.: US 2026/0156743 A1
(43) Pub. Date: Jun. 4, 2026

(54) PRINTED CIRCUIT BOARD

(71) Applicant: SAMSUNG ELECTRO-MECHANICS CO., LTD., Suwon-si (KR)

(72) Inventors: Yong Wan JI, Suwon-si (KR); Jong Eun PARK, Suwon-si (KR); Tae Hong MIN, Suwon-si (KR)

(73) Assignee: SAMSUNG ELECTRO-MECHANICS CO., LTD., Suwon-si (KR)

(21) Appl. No.: 19/174,400

(22) Filed: Apr. 9, 2025

(30) Foreign Application Priority Data
Nov. 29, 2024 (KR) 10-2024-0175658

(51) Int. Cl. H05K 1/03; H05K 1/11; H05K 3/00

(52) U.S. Cl. CPC H05K 1/0306; H05K 1/113; H05K 1/116; H05K 3/0052; H05K 2201/09481; H05K 2201/09527; H05K 2201/096; H05K 2201/09618; H05K 2201/09827; H05K 2203/0228

(57) ABSTRACT

The present disclosure relates to a printed circuit board including: a glass layer; an insulating body disposed on the glass layer, a plurality of wiring layers respectively disposed within the insulating body; and a plurality of via layers disposed respectively within the insulating body and respectively connected to at least one of the plurality of wiring layers. In a cross-section of the printed circuit board, the at least one side surface of the insulating body has a plurality of recessed portions and a plurality of protrusion portions arranged alternately in a stacking direction of the plurality of wiring layers.

### CROSS-REFERENCE TO RELATED APPLICATION(S)

This application claims benefit of priority to Korean Patent Application No. 10-2024-0175658 filed on Nov. 29, 2024, in the Korean Intellectual Property Office, the disclosure of which is incorporated herein by reference in its entirety.

### TECHNICAL FIELD

The present disclosure relates to a printed circuit board.

In order to respond to the high-performance and miniaturization strategies of semiconductors, the level of miniaturization and high-density required for printed circuit boards has increased. For example, in order to manufacture high-end products such as server boards, high-layering and large bodies are required. However, as the number of wiring layers increases and the body size increases, the board may become vulnerable to warpage. To solve this problem, the use of a glass core has been considered. However, glass may be more fragile than general epoxy-based boards. For example, there is a possibility that the glass may break due to initial cracks occurring during cutting.

### SUMMARY

An aspect of the present disclosure is to provide a printed circuit board capable of cutting a multilayer substrate including a glass layer in a relatively simple process.

Another aspect of the present disclosure is to provide a printed circuit board capable of preventing initial cracking of a glass layer during a cutting process.

Yet another aspect of the present disclosure is to provide a printed circuit board capable of minimizing stress within a glass layer by increasing a surface area of an insulating material during a cutting process.

One of the various solutions of the present disclosure is to form a stack via structure by plating on a cutting line between units when manufacturing a multilayer substrate including a glass layer, and then, removing the stack via structure formed on a cutting line by etching in a subsequent cutting process, and cutting a resin and glass residues, and the like, using a blade.

For example, a printed circuit board according to an example embodiment may include: a glass layer; an insulating body disposed on the glass layer; a plurality of wiring layers respectively disposed within the insulating body; and a plurality of via layers disposed respectively within the insulating body and respectively connected to at least one of the plurality of wiring layers. In a cross-section of the printed circuit board, least one side surface of the insulating body may have a plurality of recessed portions and a plurality of protrusion portions arranged alternately in a stacking direction of the plurality of wiring layers.

For example, a printed circuit board according to an example embodiment may include: a glass layer; a plurality of insulating layers disposed on the glass layer; a plurality of wiring layers respectively disposed within the plurality of insulating layers; and a plurality of via layers respectively disposed within the plurality of insulating layers and respectively connected to at least one of the plurality of wiring layers. One interconnected side surface of each of two insulating layers adjacent to each other in a stacking direction of the plurality of wiring layers, among the plurality of insulating layers, may have a step portion from each other in a cross-section of the printed circuit board.

For example, a printed circuit board according to an example embodiment may include: a glass layer; a plurality of insulating layers disposed on the glass layer; a plurality of wiring layers respectively disposed within the plurality of insulating layers; and a plurality of via layers respectively disposed within the plurality of insulating layers and respectively connected to at least one of the plurality of wiring layers. In a cross-section of the printed circuit board, one of the plurality of insulating layers may include one portion having a side surface recessed with a side surface of one portion of the glass layer, and another portion having a side surface substantially flat with a side surface of another portion of the glass layer.

One of the various effects of the present disclosure is to provide a printed circuit board capable of cutting a multilayer substrate including a glass layer in a relatively simple process.

Another of the various effects of the present disclosure is to provide a printed circuit board capable of preventing initial cracking of a glass layer during a cutting process.

Yet another of the various effects of the present disclosure is to provide a printed circuit board capable of minimizing stress within a glass layer by increasing a surface area of an insulating material during a cutting process.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board; and

FIGS. 3A to 3C are process cross-sectional views schematically illustrating an example of a cutting process in a process of manufacturing the printed circuit board of FIG. 2.

### DETAILED DESCRIPTION

Hereinafter, the present disclosure will be described with reference to the accompanying drawings. In the drawings, the shape and size of the elements may be exaggerated or reduced for clearer description.

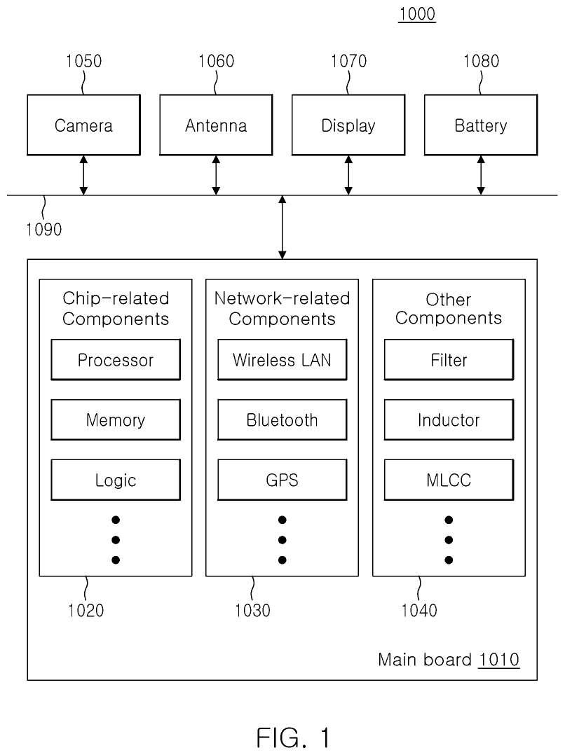

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

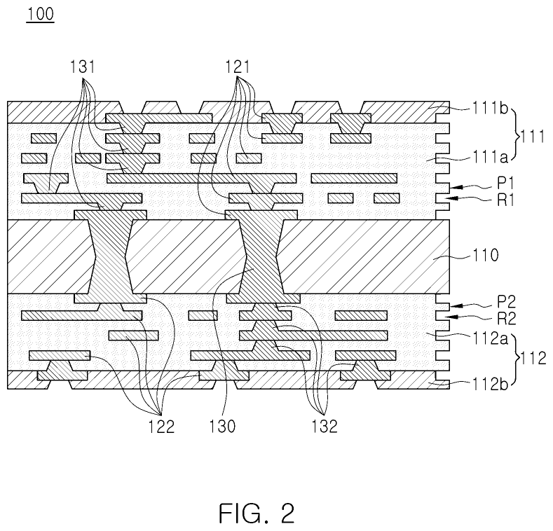

FIG. 2 is a cross-sectional view schematically illustrating an example of a printed circuit board.

Referring to FIG. 2, a printed circuit board 100 according to an example embodiment may include: a glass layer 110, a first insulating body 111 disposed on an upper surface of the glass layer 110, a plurality of first wiring layers 121 respectively disposed within the first insulating body 111, a plurality of first via layers 131 respectively disposed within the first insulating body 111, a second insulating body 112 disposed on a lower surface of the glass layer 110, a plurality of second wiring layers 122 respectively disposed within the second insulating body 112, a plurality of second via layers 132 respectively disposed within the second insulating body 112, and a metal via 130 penetrating through at least a portion of a space between the upper surface and the lower surface of the glass layer 110. The first insulating body 111 may include a plurality of first insulating layers, in which case, a first insulating layer disposed on an uppermost side, among the plurality of first insulating layers, may include a first passivation layer 111b, and the remaining first insulating layers may form a first insulating portion 111a for build-up. The second insulating body 112 may include a plurality of second insulating layers, in which case a second insulating layer disposed on a lowermost side, among the plurality of second insulating layers, may include a second passivation layer 112b, and the remaining second insulating layers may form a second insulating portion 112a for build-up. Depending on need, a build-up layer may be formed only on an upper side or a lower side of the glass layer 110, and for example, the first insulating body 111, the plurality of first wiring layers 121, and the plurality of first via layers 131 may be omitted, or the second insulating body 112, the plurality of second wiring layers 122, and the plurality of second via layers 132 may be omitted.

Meanwhile, in performing build-up using the insulating material on the glass layer and then cutting the insulating material and the glass layer into units, there may be a limit to cutting the insulating material and the glass layer at once. For example, a nanosecond ultraviolet laser may be required for cutting the insulating material, and a picosecond infrared laser may be required for cutting the glass layer. However, during this laser cutting process, initial cracks may occur in the glass layer, and the glass layer may be broken. Accordingly, it may be possible to consider forming a stack via structure by plating on a cutting line between the units during a process of forming a metal via on the glass layer and a build-up process on the glass layer, and then removing the stack via structure formed on the cutting line by etching in the cutting process, and cutting the resin and glass residues using a blade. In this case, the problems described above may be solved. For example, a multilayer substrate including a glass layer may be cut in a relatively simple process, initial cracks in the glass layer may be prevented during the cutting process, and stress in the glass layer may be minimized by increasing a surface area of the insulating material.

From this perspective, in the printed circuit board 100 that may be manufactured by the unit cutting process described above, at least one side surface of the first insulating body 111 may have a plurality of recessed portions R1 and a plurality of protrusion portions P1 alternately arranged in a stacking direction in a cross-section. Additionally, at least one side surface of the second insulating body 112 may have a plurality of recessed portions R2 and a plurality of protrusion portions P2 alternately arranged in the stacking direction in the cross-section. Additionally, at least one side surface of the glass layer 110 may be substantially flat. In this case, at least one side surface of each of the first and second insulating bodies 111 and 112 and the at least one side surface of the glass layer 110 described above may be disposed in the same direction. For example, at least one side surface of each of the first and second insulating bodies 111 and 112 described above may be connected to each other through the at least one side surface of the glass layer 110 described above in the stacking direction. Here, at least one side surface may be one side surface, but is not limited thereto, and may include each of a plurality of side surfaces.

Additionally, from this perspective, each of the plurality of recessed portions R1 disposed on at least one side surface of the first insulating body 111 may be disposed on substantially the same level as each of the plurality of first wiring layers 121, and each of the plurality of protrusion portions P1 disposed on at least one side surface of the first insulating body 111 may be disposed on substantially the same level as each of the plurality of first via layers 131. In this case, side surfaces of each of the plurality of recessed portions R1 disposed on at least one side surface of the first insulating body 111 may be recessed more inwardly than the at least one side surface of the glass layer 110, respectively, and side surfaces of each of the plurality of protrusion portions P1 disposed on at least one side surface of the first insulating body 111 may be substantially coplanar with the at least one side surface of the glass layer 110. Additionally, each of the plurality of recessed portions R2 disposed on at least one side surface of the second insulating body 112 may be disposed on substantially the same level as each of the plurality of second wiring layers 122, and each of the plurality of protrusion portions P2 disposed on at least one side surface of the second insulating body 112 may be disposed on substantially the same level as each of the plurality of second via layers 132. In this case, side surfaces of each of the plurality of recessed portions R2 disposed on at least one side surface of the second insulating body 112 may be recessed more inwardly than the at least one side surface of the glass layer 110, respectively, and side surfaces of each of the plurality of protrusion portions P2 disposed on at least one side surface of the second insulating body 112 may be substantially coplanar with at least one side surface of the glass layer 110.

Meanwhile, the shape of each of the plurality of recessed portions R1 and R2 is not particularly limited, and corners thereof may be recessed to be substantially right angles, or the corners may be recessed to be substantially curved. Additionally, the side surface of each of the plurality of recessed portions R1 and R2 may be substantially vertical, but is not limited thereto, and may be substantially curved. Additionally, the shape of each of the plurality of protrusion portions P1 and P2 is also not particularly limited, and corners thereof may protrude to be substantially right angles, or the corners may protrude to be substantially curved. Additionally, the side surfaces of each of the plurality of protrusion portions P1 and P2 may be substantially vertical, but is not limited thereto, and may be substantially curved.

In a similar perspective, in a printed circuit board 100 that may be manufactured by the above-described unit cutting process, one interconnected side surface of each of two first insulating layers adjacent to each other in the stacking direction, among the plurality of first insulating layers included in the first insulating body 111, may have a step portion in the cross-section. Additionally, one interconnected side surface of each of two second insulating layers adjacent to each other in the stacking direction, among the plurality of second insulating layers included in the second insulating body 112, may have a step portion in the cross-section. Additionally, one side surface of the glass layer 110 may be substantially flat. In this case, one interconnected side surface of each of the two first and second insulating layers adjacent to each other, respectively included in the first and second insulating bodies 111 and 112, and one side of the glass layer 110 may be disposed in the same direction. For example, one side surface of each of the plurality of first insulating layers included in the first insulating body 111 and one side surface of each of the plurality of second insulating layers included in the second insulating body 112 may be connected to each other through one side surface of the glass layer 110 in the stacking direction. Meanwhile, if necessary, such a structural feature may be substantially equally applied to not only one side surface of the plurality of first and second insulating layers included in each of the first and second insulating bodies 111 and 112 and the glass layer 110, but also other side surfaces.

Additionally, from a similar perspective, one side surface of one of the two adjacent first insulating layers included in the first insulating body 111 may be recessed more inwardly than one side surface of the other thereof. Additionally, one side surface of one of the two adjacent first insulating layers included in the first insulating body 111 may be recessed more inwardly than one side surface of the glass layer 110, and one side surface of the other thereof may be substantially coplanar with one side surface of the glass layer 110. In addition, one side surface of one of the two adjacent second insulating layers included in the second insulating body 112 may be recessed more inwardly than one side surface of the other thereof. Additionally, one side surface of one of the two adjacent second insulating layers included in the second insulating body 112 may be recessed more inwardly than one side surface of the glass layer 110, and one side surface of the other side thereof may be substantially coplanar with one side surface of the glass layer 110.

Meanwhile, a printed circuit board 100 according to an example embodiment of such a structure may be a multilayer and large-area board that may be used for a large-capacity server, and the like, but the present disclosure is not limited thereto. Additionally, the printed circuit board 100 may be a package board and/or an interposer board, but the present disclosure is not limited thereto.

Hereinafter, components of a printed circuit board 100 according to an example embodiment will be described in more detail with reference to the drawings.

The glass layer 110 may include glass, which is an amorphous solid. The glass may include, for example, pure silicon dioxide (about 100% SiO₂), soda-lime glass, borosilicate glass, alumino-silicate glass, etc. However, the present disclosure is not limited thereto, and alternative glass materials, for example, fluorine glass, phosphate glass, chalcogen glass, or the like, may also be used as materials. Additionally, other additives may be further included to form a glass having specific physical properties. Such additives may include calcium carbonate (e.g., lime) and sodium carbonate (e.g., soda), as well as magnesium, calcium, manganese, aluminum, lead, boron, iron, chromium, potassium, sulfur, and antimony, and carbonates and/or oxides of these element and other elements. Meanwhile, the glass layer 110 may be distinguished from an organic insulating material including glass fiber (Glass Fiber, Glass Cloth or Glass Fabric), such as CCL (Copper Clad Laminate), PPG (Prepreg), or the like. The glass layer 110 may be, for example, in the form of a glass plate. A through-hole in which the metal via 130 is disposed may penetrate between the upper and lower surfaces of the glass layer 110. The glass layer 110 may have an approximately rectangular shape on a plane, but the present disclosure is not limited thereto.

The metal via 130 may include a metal. The metal may include copper (Cu), aluminum (Al), silver (Ag), tin (Sn), gold (Au), nickel (Ni), lead (Pb), titanium (Ti), and/or alloys thereof. For example, the metal via 130 may include a titanium layer and a copper layer formed by sputtering, that is, sputtered titanium and sputtered copper, as a seed layer, and may include electrolytic copper formed by electrolytic plating as a plating layer based thereon. If necessary, the metal via 130 further include chemical copper formed by electroless plating on the titanium layer and the copper layer formed by sputtering as a seed layer. The metal via 130 may perform various functions depending on the design. For example, the metal via 130 may include a through-via for signal transmission, a through-via for power transmission, and a through-via for ground transmission. The metal via 130 may include a filled via in which at least a portion of the through-hole is filled with a metal. The metal via 130 may have a substantially hourglass shape, but may also have a substantially cylindrical shape. The upper surface and the lower surface of the metal via 130 may be recessed more inwardly than the upper surface and the lower surface of the glass layer 110, respectively, and therefore, the upper surface and the lower surface of the metal via 130 may have a step portion from the upper surface and the lower surface of the glass layer 110, respectively, but the present disclosure is not limited thereto. The metal via 130 may be provided in plural.

Each of the first and second insulating bodies 111 and 112 may include an insulating material. The insulating material may include a thermosetting resin such as an epoxy resin, a thermoplastic resin such as a polyimide, or an inorganic filler, an organic filler, and/or glass fiber (glass cloth, glass fabric) together with the resin. For example, the insulating material may include Prepreg (PPG), an Ajinomoto Build-up Film (ABF), a Photoimageable Dielectric (PID), and a Solder Resist (SR), but the present disclosure is not limited thereto. The first insulating body 111 may include a plurality of first insulating layers. Each of the plurality of first insulating layers may include the insulating material described above. A first insulating layer disposed on an uppermost side, among the plurality of first insulating layers, may include a first passivation layer 111b, and the remaining first insulating layers may form a first insulating portion 111a for build-up. The first insulating portion 111a and the first passivation layer 111b may include different insulating materials, but the present disclosure is not limited thereto. The remaining first insulating layers included in the first insulating portion 111a may have distinct boundaries, or may be integrated with each other to the extent that the boundaries therebetween may not be readily identified. The second insulating body 112 may include a plurality of second insulating layers. Each of the plurality of second insulating layers may include the insulating material described above. A second insulating layer disposed on a lowermost side, among the plurality of second insulating layers, may include a second passivation layer 112b, and the remaining second insulating layers may form a second insulating portion 112a for build-up. The second insulating portion 112a and the second passivation layer 112b may include different insulating materials, but the present disclosure is not limited thereto. The remaining first insulating layers included in the second insulating portion 112a may have distinct boundaries, or may be integrated with each other to the extent that the boundaries therebetween may not be readily identified. The first passivation layer 111b may have a plurality of first openings respectively exposing at least a portion of the first wiring layer disposed on an uppermost side, among the plurality of first wiring layers 121. The second passivation layer 112b may have a plurality of second openings respectively exposing at least a portion of the second wiring layer disposed on a lowermost side, among the plurality of second wiring layers 122. A pattern exposed through each of the first and second openings may be of a Solder Mask Defined (SMD) type and/or a Non Solder Mask Defined (NSMD) type, but the present disclosure not limited thereto.

Each of the plurality of first and second wiring layers 121 and 122 may include a metal. The metal may include copper (Cu), aluminum (Al), silver (Ag), tin (Sn), gold (Au), nickel (Ni), lead (Pb), titanium (Ti), and/or alloys thereof. For example, each of the plurality of first and second wiring layers 121 and 122 may include chemical copper formed by electroless plating as a seed layer, and may include electrolytic copper formed by electrolytic plating as a plating layer based thereon. Each of the plurality of first and second wiring layers 121 and 122 may perform various functions according to the design. For example, each of the plurality of first and second wiring layers 121 and 122 may include a signal pattern, a power pattern, and a ground pattern. Each of the patterns may have various shapes such as a line, a trace, a plane, a land, a pad, a land, or the like. A first wiring layer disposed on a lowermost side, among the plurality of first wiring layers 121, may be connected to an upper side of the metal via 130. A second wiring layer disposed on an uppermost side, among the plurality of second wiring layers 122, may be connected to a lower side of the metal via 130. If necessary, the first wiring layer on the lowermost side and the second wiring layer on the uppermost side may not be directly connected to the metal via 130 but may be connected through a connection via. In this case, the metal via 130 may have a structure without a pad or a land.

Each of the plurality of first and second via layers 131 and 132 may include a metal. The metal may include copper (Cu), aluminum (Al), silver (Ag), tin (Sn), gold (Au), nickel (Ni), lead (Pb), titanium (Ti), and/or alloys thereof. For example, each of the plurality of first and second via layers 131 and 132 may include chemical copper formed by electroless plating as a seed layer, and may include electrolytic copper formed by electrolytic plating as a plating layer based on the chemical copper. Each of the plurality of first and second via layers 131 and 132 may perform various functions according to the design. For example, each of the plurality of first and second via layers 131 and 132 may include a connection via for signal transmission, a connection via for power transmission, and a connection via for ground transmission. Each of the plurality of first and second via layers 131 and 132 may ach include a filled via that fills at least a portion of a via hole with metal, but may also include a conformal via in which the metal is disposed along a wall surface of the via hole. The plurality of first and second via layers 131 and 132 may each include a plurality of connection vias. For example, the plurality of first via layers 131 may include at least one first connection via that is substantially tapered so that a width of an upper end thereof is wider than a width of a lower end thereof in a cross-section. Additionally, the plurality of second via layers 132 may include at least one second connection via that is substantially tapered so that a width of a lower end thereof is wider than a width of an upper end thereof in the cross-section.

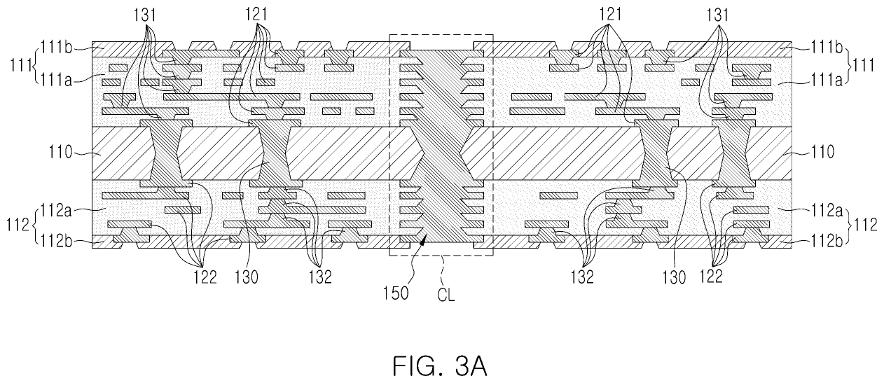

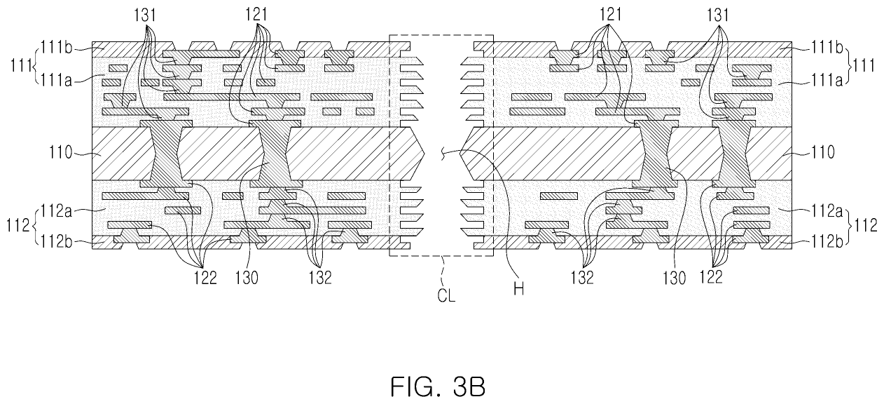

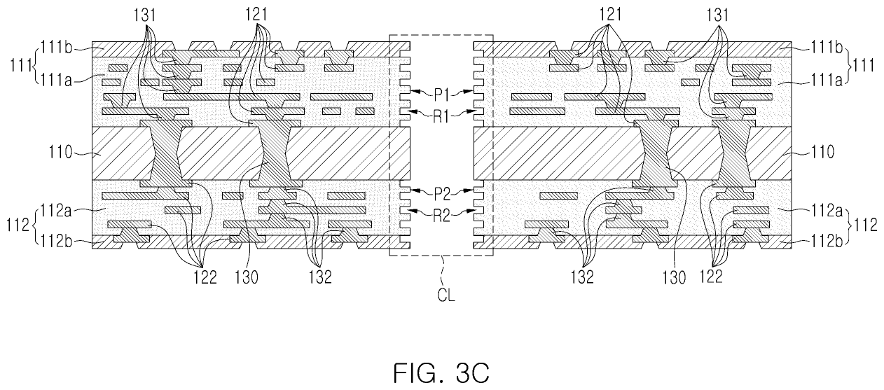

FIGS. 3A to 3C are process cross-sectional views schematically illustrating an example of a cutting process during the manufacturing process of the printed circuit board of FIG. 2.

Referring to FIG. 3A, a multilayer substrate having a plurality of units and a cutting region CL between the plurality of units may be prepared on a panel level. Each of the plurality of units may include a structure in which first and second insulating bodies 111 and 112, a plurality of first and second wiring layers 121 and 122, and a plurality of first and second via layers 131 and 132 are disposed on both sides of a glass layer 110 having a metal via 130 therein. A stack via structure 150 formed by plating may be formed in the cutting region CL. When forming the metal via 130 of each of the plurality of units, the plurality of first and second wiring layers 121 and 122 and the plurality of first and second via layers 131 and 132, the stack via structure 150 may be formed together on substantially the same level in each layer. For example, the stack via structure 150 may include a via layer penetrating through the glass layer 110 and a plurality of pattern layers and a plurality of via layers respectively disposed in the first and second insulating bodies 111. An opening may be formed in the first and second passivation layers 111b and 112b of each of the first and second insulating bodies 111 and 112 so that an upper surface and a lower surface of the stack via structure 150 are exposed.

Referring to FIG. 3B, the stack via structure 150 formed in the cutting region CL may be removed. For example, a metal etching process may be performed through the above-described opening formed in each of the first and second passivation layers 111b and 112b, thus removing the stack via structure 150. In this case, a through-portion H configured to identify a plurality of units may be formed in the cutting region CL without two types of laser equipment for cutting each of the glass layer and the insulating material. Accordingly, the process may be relatively simple, and the process costs may also be reduced. Additionally, the occurrence of initial cracks in the glass layer 110 may be prevented. Additionally, the stress occurring in the glass layer 110 may be minimized due to the increase in the surface area of the insulating material.

Referring to FIG. 3C, resin or glass residue remaining in the cutting region CL may be removed. For example, a portion of the through-portion H may be cut using a blade. In this case, a plurality of recessed portions R1 and R2 and a plurality of protrusion portions P1 and P2 as described above may be formed on a side surface disposed in the cutting region CL of the first and second insulating bodies 111 and 112 of each unit. Additionally, the side surface disposed in the cutting region CL of the glass layer 110 may be substantially flat. In this manner, the cutting process according to an example embodiment may be relatively simple as described above, and the process costs may be reduced, and the initial crack may be prevented from occurring in the glass layer 110 during the cutting process. Additionally, the stress occurring in the glass layer 110 may be minimized due to the increase in the surface area of the insulating material.

The printed circuit board 100 according to the example embodiment described above may be manufactured through a series of processes, and other contents may be substantially the same as described above.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component.

In the present disclosure, being disposing in a through-hole or a via-hole may include not only a case in which an object is disposed completely in the through-hole or the via-hole, but also a case in which the object protrudes upwardly or downwardly in a cross-section. For example, when the object may be disposed within the through-hole or the via-hole on a plane, the object may be determined to be disposed within the through-hole or the via-hole in a broader sense.

In the present disclosure, determination may be performed by including process errors, positional deviations, errors at the time of measurement, which may occur in a manufacturing process. For example, substantially the same direction may include not only the completely same direction but also the approximately the same direction. Furthermore, substantially coplanar may include not only the case of being completely coplanar but also the case of being approximately coplanar. Furthermore, substantially having a specific shape may include not only the case of having such a shape completely but also the case of having such a shape approximately. Furthermore, substantially flat may include not only the case of being completely flat but also the case of being approximately flat. Furthermore, substantially the same insulating material may mean not only the case of being the completely same insulating material but also the case of including the same type of insulating material. Accordingly, the composition of the insulating material may be substantially the same, but the specific composition ratio thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Additionally, the term electrically connected includes both physically connected and not physically connected. Additionally, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a glass layer;
an insulating body disposed on the glass layer;
a plurality of wiring layers respectively disposed within the insulating body; and
a plurality of via layers disposed respectively within the insulating body and respectively connected to at least one of the plurality of wiring layers,
wherein in a cross-section of the printed circuit board, at least one side surface of the insulating body has a plurality of recessed portions and a plurality of protrusion portions arranged alternately in a stacking direction of the plurality of wiring layers.

2. The printed circuit board according to claim 1, wherein each of the plurality of recessed portions is disposed on substantially the same level as each of the plurality of wiring layers, and
each of the plurality of protrusion portions is disposed on substantially the same level as each of the plurality of via layers.

3. The printed circuit board according to claim 1, wherein at least one side surface of the glass layer is substantially flat.

4. The printed circuit board according to claim 3, wherein a side surface of each of the plurality of recessed portions, disposed on a same side of the printed circuit board as the at least one side surface of the glass layer, is recessed more inwardly than the at least one side surface of the glass layer.

5. The printed circuit board according to claim 3, wherein a side surface of each of the plurality of protrusion portions, disposed on a same side of the printed circuit board as the at least one side surface of the glass layer, is substantially coplanar with the at least one side surface of the glass layer.

6. The printed circuit board according to claim 1, wherein the insulating body includes a first insulating body disposed on an upper surface of the glass layer and a second insulating body disposed on a lower surface of the glass layer,
the plurality of wiring layers include a plurality of first wiring layers respectively disposed within the first insulating body and a plurality of second wiring layers respectively disposed within the second insulating body,
the plurality of via layers include a plurality of first via layers respectively disposed within the first insulating body and respectively connected to at least one of the plurality of first wiring layers and a plurality of second via layers respectively disposed within the second insulating body and respectively connected to at least one of the plurality of second wiring layers, and
at least one side surface of each of the first and second insulating bodies disposed in the same direction has the plurality of recessed portions and the plurality of protrusion portions.

7. The printed circuit board according to claim 6, further comprising:
a metal via penetrating through at least a portion of a space between the upper surface and the lower surface of the glass layer,
wherein a first wiring layer disposed on a lowermost side, among the plurality of first wiring layers, and a second wiring layer disposed on an uppermost side, among the plurality of second wiring layers, are connected to the metal via, respectively.

8. The printed circuit board according to claim 6,
wherein each of the plurality of first via layers includes at least one first connection via that is substantially tapered so that a width of an upper end thereof is wider than a width of a lower end thereof in the cross-section, and
each of the plurality of second via layers includes at least one second connection via that is substantially tapered so that a width of a lower end thereof is wider than a width of an upper end in the cross-section.

9. A printed circuit board, comprising:
a glass layer;
a plurality of insulating layers disposed on the glass layer;
a plurality of wiring layers respectively disposed within the plurality of insulating layers; and
a plurality of via layers respectively disposed within the plurality of insulating layers and respectively connected to at least one of the plurality of wiring layers,
wherein one interconnected side surface of each of two insulating layers adjacent to each other in a stacking direction of the plurality of wiring layers, among the plurality of insulating layers, has a step portion from each other in a cross-section of the printed circuit board.

10. The printed circuit board according to claim 9,
wherein one side surface of one of the two insulating layers adjacent to each other is recessed more inwardly than the other side surface thereof.

11. The printed circuit board according to claim 9,
wherein one side surface of the glass layer disposed in a same side as the one interconnected side surface of each of the two insulating layers adjacent to each other is substantially flat.

12. The printed circuit board according to claim 11,
wherein one side surface of one of the two insulating layers adjacent to each other is recessed more inwardly than the one side surface of the glass layer, and
one side surface of the other of the two insulating layers adjacent to each other is substantially coplanar with the one side surface of the glass layer.

13. The printed circuit board according to claim 9,
wherein the plurality of insulating layers include a plurality of first insulating layers disposed on an upper surface of the glass layer and a plurality of second insulating layers disposed on a lower surface of the glass layer,
the plurality of wiring layers include a plurality of first wiring layers respectively disposed within the plurality of first insulating layers and a plurality of second wiring layers respectively disposed within the plurality of second insulating layers,
the plurality of via layers include a plurality of first via layers respectively disposed within the plurality of first insulating layers and respectively connected to at least one of the plurality of first wiring layers, and a plurality of second via layers respectively disposed within the plurality of second insulating layers and respectively connected to at least one of the plurality of second wiring layers,
one interconnected side surface of each of two first insulating layers adjacent to each other in the stacking direction, among the plurality of first insulating layers, has a step portion from each other in the cross-section,
one interconnected side surface of each of two second insulating layers adjacent to each other in the stacking direction, among the plurality of second insulating layers, has a step portion from each other in the cross-section, and
one interconnected side surface of each of the two first insulating layers adjacent to each other and one interconnected side surface of each of the two second insulating layers adjacent to each other are disposed on a same side of the printed circuit board.

14. The printed circuit board according to claim 13, further comprising:
a metal via penetrating through at least a portion of a space between the upper surface and the lower surface of the glass layer,
wherein a first wiring layer disposed on a lowermost side, among the plurality of first wiring layers, and a second wiring layer disposed on an uppermost side, among the plurality of second wiring layers, are connected to the metal via, respectively.

15. The printed circuit board according to claim 13,
wherein each of the plurality of first via layers includes at least one first connection via that is tapered so that a width of an upper end thereof is wider than a width of a lower end thereof in the cross-section, and
each of the plurality of second via layers includes at least one second connection via that is tapered so that a width of a lower end thereof is wider than a width of an upper end thereof in the cross-section.

16. The printed circuit board according to claim 9,
wherein the first insulating layer disposed on an uppermost side, among the plurality of first insulating layers, includes a first passivation layer having a plurality of first openings respectively exposing at least a portion of the first wiring layer disposed on an uppermost side, among the plurality of first wiring layers, and
the second insulating layer disposed on a lowermost side, among the plurality of second insulating layers, includes a second passivation layer having a plurality of second openings respectively exposing at least a portion of the second wiring layer disposed on a lowermost side, among the plurality of second wiring layers.

17. A printed circuit board, comprising:
a glass layer;
a plurality of insulating layers disposed on the glass layer;
a plurality of wiring layers respectively disposed within the plurality of insulating layers; and
a plurality of via layers respectively disposed within the plurality of insulating layers and respectively connected to at least one of the plurality of wiring layers,
wherein in a cross-section of the printed circuit board, one of the plurality of insulating layers includes one portion having a side surface recessed with a side surface of one portion of the glass layer, and another portion having a side surface substantially flat with a side surface of another portion of the glass layer.

18. The printed circuit board according to claim 17, wherein the one portion of the one of the plurality of insulating layers having the side surface recessed with the side surface of the one portion of the glass layer is disposed on substantially the same level as one of the plurality of wiring layers.

19. The printed circuit board according to claim 17, further comprising:
a metal via penetrating through at least a portion of a space between an upper surface and a lower surface of the glass layer to connect wiring layers, among the plurality of wiring layers, disposed on the upper surface and the lower surface of the glass layer.

20. The printed circuit board according to claim 19,
wherein a via layer, among the plurality of via layers, disposed on the upper surface of the glass layer, is substantially tapered so that a width of an upper end thereof is wider than a width of a lower end thereof in the cross-section, and
a via layer, among the plurality of via layers, disposed on the lower surface of the glass layer, is substantially tapered so that a width of a lower end thereof is wider than a width of an upper end in the cross-section.
